(19) United States
(12) Patent Application Publication
(10) Pub. No.: US 2009/0096115 A1
(43) Pub. Date: Apr. 16, 2009

(54) Semiconductor package and method for fabricating the same

(75) Inventors: Chien-Ping Huang, Hsinchu Hsein (TW); Han-Ping Pu, Taichung (TW); Ho-Yi Tsai, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/818,050

(22) Filed: Jun. 12, 2007

(30) Foreign Application Priority Data
Jun. 13, 2006 (TW) 095120914

(51) Int. Cl. H01L 23/42; H01L 21/02; H01L 23/28

(52) U.S. Cl. 257/796; 438/127; 438/108; 257/E21.002; 257/E23.116; 257/E23.087

(57) ABSTRACT

A semiconductor package and a method for fabricating the same are disclosed. The present invention discloses mounting and electrically connecting a semiconductor chip to a chip carrier, forming an interfacial layer or a heat-dissipating member having the interfacial layer on the semiconductor chip, and forming an encapsulant for covering the semiconductor chip, the interfacial layer or the heat dissipating member. The method further includes cutting the encapsulant along edges of the interfacial layer, and removing the redundant encapsulant on the interfacial layer so as to expose the semiconductor chip or the heat-dissipating member without forming burr or heavily wearing cutting tools.

### FIELD OF THE INVENTION

The present invention relates to semiconductor packages and methods for fabricating the same, and more particularly, to a semiconductor package that can dissipate heat efficiently and a method for fabricating the same.

### BACKGROUND OF THE INVENTION

Along with growing demands for lighter, thinner, smaller and shorter electronic products, semiconductor packages integrated with high-density electronic components and electronic circuits have become a mainstream. However, because such miniaturized but highly integrated packages often produce a surprisingly large amount of heat during operation, it becomes extremely important to find a way to dissipate the heat immediately and efficiently, in order to avoid the heat from being accumulated and adversely affecting performance and stability of semiconductor chips. Additionally, in order to protect internal circuits of the semiconductor packages from mist and dust, surfaces of the semiconductor chip must be covered by an encapsulant. Nevertheless, as the encapsulant is made of packaging resin having a remarkably low thermal conductivity around 0.8 w/m-° K, it is quite difficult to efficiently dissipate heat generated from active surfaces of the semiconductor chips to external environment via the encapsulant. In order to overcome such disadvantages, it has been proposed to form a semiconductor package equipped with a heat-dissipating member so at to improve efficiency of heat dissipation.

However, if the heat-dissipating member is completely encapsulated by the encapsulant, efficiency of heat dissipation can be hardly improved, because the heat cannot be dissipated without passing through the encapsulant. Therefore, recent semiconductor packages are configured to expose surfaces of heat dissipating members or semiconductor chips from encapsulants so as to efficiently dissipate the heat.

For example, as shown in FIG. 1A, a semiconductor package 10 disclosed by U.S. Pat. No. 5,450,283 comprises a the semiconductor chip 11 having a top surface thereof directly exposed from an encapsulant 14, so as to dissipate the heat generated the semiconductor chip 11 to ambient atmosphere directly, without passing through the encapsulant 14.

Nevertheless, the foregoing semiconductor package 10 and fabrication method thereof have some serious drawbacks. To be more specific, referring to FIG. 1B in conjunction with FIG. 1A, during a molding process, before placing the semiconductor chip 11 attached to a substrate 12 into a mold cavity 15 of a packaging mold for forming the encapsulant 14, a tape 13 has to be provided and attached to a top wall of the mold cavity 15, such that the tape 13 is interposed between a top surface of the semiconductor chip 11 and the top wall of the mold cavity 15 once the mold is clamped, so as to prevent mold flash from occurring on top of the semiconductor chip 11. However, if the semiconductor chip 11 is improperly attached to the substrate 12 or not perfectly abutted against the top wall of the mold cavity 15 via the tape 13, a gap may be formed between the top surface of the semiconductor chip 11 and the upper wall of the mold cavity 15 because the summation of height of the semiconductor chip 13 and the substrate 12 is not high enough. As a result, the packaging materials flow into the gap therebetween and flash over the top surface of the semiconductor chip 11. This thereby adversely affects heat dissipation of the semiconductor chip 11 and appearance of the semiconductor package.

Accordingly, a deflash process has to be performed to remove the mold flash on the top surface of the semiconductor chip 11, thereby increasing the fabrication time and the fabrication cost. Moreover, the semiconductor package may be easily damaged under the deflash process. On the other hand, if the summation of the height of the substrate 12 and the semiconductor chip 11 is too high, the semiconductor chip 11 can be easily damaged and cracked because the top surface of the semiconductor chip 11 is abutted to the top wall of the mold cavity 15 with overload stress. The clamping force of the mold may be exceeded and transferred to the semiconductor chip 11 and thus cause cracking of the semiconductor chip 11.

In order to overcome the aforementioned disadvantages, U.S. Pat. No. 6,750,082 discloses another kind of semiconductor package, wherein a polishing process is performed to remove the encapsulant covering on the semiconductor chip so as to expose a surface of the semiconductor chip from the encapsulant. Despite the fact that the polishing process may be costly, the semiconductor chip is often not sufficiently exposed but severely damaged during the polishing process due to warpage of the semiconductor package caused by uneven stress. In addition, during the polishing process, the semiconductor chip may be easily damaged or cracked by polishing stress.

To solve the foregoing problems, U.S. Pat. No. 6,458,626 (as shown in FIGS. 2A to 2C), U.S. Pat. No. 6,444,498 (as shown in FIG. 3), and U.S. Pat. No. 6,699,731 (as shown in FIG. 4) with the inventors and the assignees of the aforementioned patents being the same as those of the present application, respectively disclose semiconductor packages, which can comprise heat dissipating members mounted on semiconductor chips without cracking the semiconductor chips or forming mold flash, or expose surfaces of the semiconductor chips from the semiconductor packages.

In brief, referring to FIG. 2A to 2C in conjunction with FIGS. 3 and 4, the foregoing semiconductor packages are fabricated by the following steps including: forming an interfacial layer 25 on a heat sink 21 first; directly adhering the heat sink 21 to a semiconductor chip 20 on a substrate 23; performing a molding process to form an encapsulant 24 completely encapsulating the heat sink 21 and the semiconductor chip 20, wherein the interfacial layer 25 formed on the heat sink 21 is covered by the encapsulant 24 and poorly bonded thereto (as shown in FIG. 2A); performing a cutting process (as shown in FIG. 2B) to remove a portion of the encapsulant 24 that is formed on the heat sink 21. Because the bonding force between the interfacial layer 25 (such as a gold plated layer) and the heat sink 21 is greater than that between the interfacial layer 25 and the encapsulant 24, the interfacial layer 25 can be retained on the heat sink 21 without holding any portion of the encapsulant 24 on the interfacial layer 25 (as shown in FIG. 2C) during the removing process, thereby preventing mold flash from occurring.

Moreover, if the bonding force between the interfacial layer 25 (such as a P.I. tape) and the encapsulant 24 is greater than that between the interfacial layer 25 and the heat sink 21, the encapsulant 24 and the interfacial layer 25 can be moved at once during the removing process (as shown in FIG. 3), thereby avoiding encapsulating materials from covering the heat sink 21.

In addition, as shown in FIG. 4, the semiconductor package comprises a covering plate 33 formed on a semiconductor chip 31, wherein the covering plate is made of a metal material and further comprises an interfacial layer 333. Due to the coefficient of thermal expansion mismatch between the interfacial layer 333 and an encapsulant 34, the interfacial layer 333 can be easily detached from the semiconductor chip 31 and portions of the encapsulant 34 surrounding the semiconductor chip 31, such that the interfacial layer 333, the covering plate 33 and a portion 340 of the encapsulant 34 formed thereon can be removed from the semiconductor chip 31 and the encapsulant 34 at once, so as to expose a surface of the semiconductor chip 31 from the encapsulant 34. This thereby allows the heat generated by the semiconductor chip 31 to be directly dissipated to external ambient via the exposed surface of the semiconductor chip 31.

Furthermore, during the molding process, as the top surface of the semiconductor chip 31 is covered by the interfacial layer 333, the top surface of the semiconductor chip 31 can be free of encapsulating materials without employing any deflashing process, thereby not only reducing the cost of production but also improving the appearance of the semiconductor package.

According to the fabrication methods of the foregoing prior-arts, cutting tools are set to cut through the heat sink during the cutting process. However, as the heat sink is made of a metal material such as copper and aluminum, employing a cutting tool such as a diamond-cutting tool to cut through the heat sink is likely to form uneven sharp edges (also known as burrs) on the periphery of the heat sink, thereby forming unpleasant outlook of the package and causing severely detritions of the cutting tool as well as increasing cost of production and decreasing yield of production.

Accordingly, a need still remains for providing a semiconductor package and a fabrication method thereof, which requires no polishing process and is capable of dissipating heat efficiently and avoiding damages of a semiconductor chip as well as reducing abrasion of cutting tools.

Solutions to these problems have been long sought but prior developments have not taught or suggested any solutions, and thus solutions to these problems have long eluded those skilled in the art.

### SUMMARY OF THE INVENTION

In light of the shortcomings of the above prior arts, a primary objective of the present invention is to provide a semiconductor package and a method for fabricating the same, which can dissipate heat and prevent the semiconductor chip from being compressed and damaged during the molding process.

Another objective of the present invention is to provide a semiconductor package and a method for fabricating the same, which can expose the semiconductor chip without undergoing a polishing process, so as to avoid cracking of the semiconductor chip and reduce the fabrication cost.

A further objective of the present invention is to provide a semiconductor package and a method for fabricating the same, which can prevent cutting tools from cutting through a heat-dissipating member, thereby avoiding problems such as burr and wearing of the cutting tools during a cutting process so as to reduce the cost of cutting process.

To achieve the aforementioned and other objectives, a method for fabricating a semiconductor package of the present invention comprises the steps of: attaching and electrically connecting a semiconductor chip to a chip carrier; forming an interfacial layer on a surface of the semiconductor chip not attaching to the chip carrier; performing a molding process so as to form an encapsulant on the chip carrier for encapsulating the semiconductor chip and the interfacial layer; performing a cutting process so as to cut the encapsulant along periphery of the interfacial layer with a cutting depth being set at least as deep as the interfacial layer; and performing a removing process for removing a portion of the encapsulant formed on the interfacial layer.

The interfacial layer may be a polyimide (P.I.) tape, an epoxy resin, or an organic layer, which makes the bonding force between the interfacial layer and the encapsulant greater than that between the interfacial layer and the semiconductor chip, such that the interfacial layer and the encapsulant formed thereon can be removed at once during the removing process so as to expose a surface of the semiconductor chip for heat dissipation. Further, an external heat-dissipating member may be disposed on the exposed surface of the semiconductor chip to enhance heat dissipation. On the other hand, the interfacial layer may be made of a material such as gold (Au) or nickel (Ni), which makes the bonding force between the interfacial layer and the semiconductor chip greater than that between the interfacial layer and the encapsulant, such that only a portion of the encapsulant located on the interfacial layer is removed during the removing process, so as to expose the interfacial layer, thereby dissipating heat generated by the semiconductor chip to external ambient air via the interfacial layer.

Yet, another method for fabricating the semiconductor package of the present invention comprises the steps of: mounting and electrically connecting a semiconductor chip to a chip carrier; attaching a heat-dissipating member on a surface of the semiconductor chip not attaching to the chip carrier, wherein a surface of the heat-dissipating member not attaching to the semiconductor chip is provided with an interfacial layer; performing a molding process to form an encapsulant on the chip carrier for encapsulating the semiconductor chip, the heat-dissipating member, and the interfacial layer; performing a cutting process to cut the encapsulant along periphery of the interfacial layer and the heat dissipating member with a cutting depth being held at least as deep as the interfacial layer; and performing a removing process to remove a portion of the encapsulant formed on the interfacial layer.

The interfacial layer may be a P.I. tape, an epoxy resin, or an organic layer, which makes the bonding force between the interfacial layer and the encapsulant greater than that between the interfacial layer and the heat-dissipating member, such that the interfacial layer and a portion of the encapsulant formed thereon can be removed at once during the removing process, so as to expose a surface of the heat-dissipating member for heat dissipation. Alternatively, the interfacial layer may be made of a material such as gold (Au) or nickel (Ni), which makes the bonding force between the interfacial layer and the heat-dissipating member greater than that between the interfacial layer and the encapsulant, such that a portion of the encapsulant located on the interfacial layer can be removed to expose the interfacial layer during the removing process, so as to dissipate heat to external environment via the heat-dissipating member and the interfacial layer.

Furthermore, the chip carrier may be a substrate or a leadframe, and the semiconductor chip may be electrically connected to the chip carrier by means of flip-chip techniques or wire-bonding techniques. If the semiconductor chip is electrically connected to the chip carrier by the flip-chip techniques, the interfacial layer or the heat dissipating member having the interfacial layer may be directly disposed on an non-active surface of the semiconductor chip. On the other hand, if the semiconductor chip is electrically connected to the chip carrier via bonding wires, a material layer such as a dummy chip may be disposed on an active surface of the semiconductor chip without interfering with the bonding wires, and then the interfacial layer or the heat dissipating member having the interfacial layer may be disposed on top of the material layer.

According to the aforementioned, a semiconductor package is disclosed, comprising: a chip carrier; a semiconductor chip mounted on and electrically connected to the chip carrier; and an encapsulant formed on the chip carrier for encapsulating the semiconductor chip, wherein the encapsulant is formed with a recess corresponding in position to the semiconductor chip so as to expose the semiconductor chip from the encapsulant. Moreover, an interfacial layer or a heat-dissipating member having an interfacial layer may be formed on a surface of the semiconductor chip corresponding in position to the recess of the encapsulant so as to enhance heat dissipation.

Therefore, as aforementioned, the present invention primarily features in attaching and electrically connecting a semiconductor chip to a chip carrier; forming an interfacial layer or attaching a heat dissipating member having an interfacial layer on the semiconductor chip; forming an encapsulant on the chip carrier for encapsulating the semiconductor chip and the interfacial layer or the heat dissipating member having the interfacial layer, wherein a space is kept between the top surface of the encapsulant and the top surface of the interfacial layer so as to prevent cracking of the semiconductor chip during the molding process; subsequently, cutting the encapsulant along the periphery of the interfacial layer or the periphery of the heat dissipating member having the interfacial layer; and removing the excess or unneeded encapsulant from the interfacial layer so as to dissipate heat and avoid mold flash, wherein the interfacial layer can be left over or removed with the excess encapsulant.

Accordingly, during fabrication of the present invention, a common polishing process existed in the prior art can be omitted so as to prevent exposing the semiconductor chip to the external environment, thereby avoiding problems such as cracking the semiconductor chip and increasing the cost of production. Moreover, during the cutting process, instead of cutting through the interfacial layer or the heating-dissipating member, the encapsulant of the present invention is cut along the periphery of the interfacial layer or the periphery of the heating-dissipating member, thereby preventing problems such as burr and wearing of cutting tools as well as reducing the cost of the cutting process the heat sink package structure and the method for fabricating the same mainly comprises the steps of mounting and electrically connecting a semiconductor chip to a chip carrier; mounting an interfacial layer or a heat dissipating member having an interfacial layer on the semiconductor chip; forming an encapsulant that encapsulates the semiconductor chip and the interfacial layer or the heat dissipating member having the interfacial layer, wherein a spacing is kept between the top surface of the encapsulant and the interfacial layer so as to prevent cracking of the semiconductor chip during the molding process; subsequently, cutting the encapsulant along edges of the interfacial layer or the heat dissipating member having the interfacial layer; and removing the redundant encapsulant located on the interfacial layer, wherein the interfacial layer can be removed together with the encapsulant thereon or can be left intact. Thus, a heat sink package structure is formed without undergoing a conventional polishing process, thereby avoiding the cracking of the semiconductor chip which may otherwise arise from polishing the encapsulant as taught in the prior art. Since the cutting line does not pass through the heat-dissipating member, the burr problem and wearing of cutting tools can be prevented and thus the cutting cost can be reduced.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF DRAWINGS

The present invention can be more fully understood by reading the following detailed description of the preferred embodiments, with reference made to the accompanying drawings, wherein:

FIGS. 1A and 1B (PRIOR ART) are cross-sectional views of a semiconductor package disclosed by U.S. Pat. No. 5,450,283;

FIGS. 2A to 2C (PRIOR ART) are cross-sectional views of a semiconductor package disclosed by U.S. Pat. No. 6,458,626;

FIG. 3 is a cross-sectional view of a semiconductor package disclosed by U.S. Pat. No. 6,444,498;

FIG. 4 is a cross-sectional view of a semiconductor package disclosed by U.S. Pat. No. 6,699,731;

FIGS. 5A to 5D are schematic views showing a semiconductor package and a method for fabricating the same according to a first embodiment of the present invention;

FIG. 5C′ is a schematic cross-sectional view showing an alternative structure of FIG. 5C;

FIGS. 6A to 6C are schematic views showing a semiconductor package and a method for fabricating the same according to a second embodiment of the present invention;

FIGS. 7A and 7B are schematic views showing a semiconductor package according to a third embodiment of the present invention;

FIG. 8 is a schematic view showing a semiconductor package according to a fourth embodiment of the present invention;

FIGS. 9A to 9D are schematic views showing a semiconductor package and a method for fabricating the same according to a fifth embodiment of the present invention;

FIGS. 10A to 10B are schematic views showing a semiconductor package and a method for fabricating the same according to a sixth embodiment of the present invention;

FIG. 11 is a schematic view showing a semiconductor package according to a seventh embodiment of the present invention;

FIGS. 12A and 12B are schematic views showing a semiconductor package and a method for fabricating the same according to an eighth embodiment of the present invention; and

FIG. 13 is a schematic view showing a semiconductor package according to a ninth embodiment of the present invention.

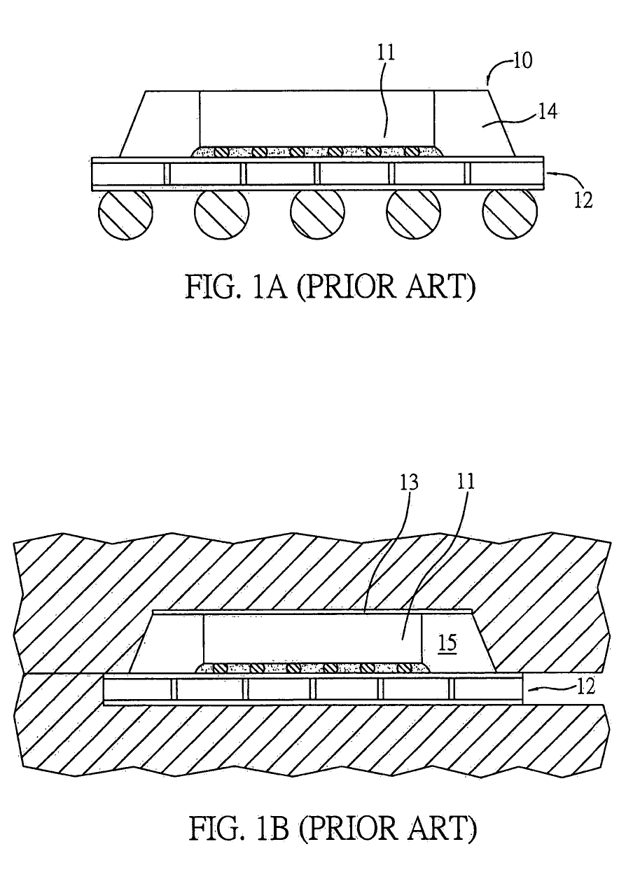

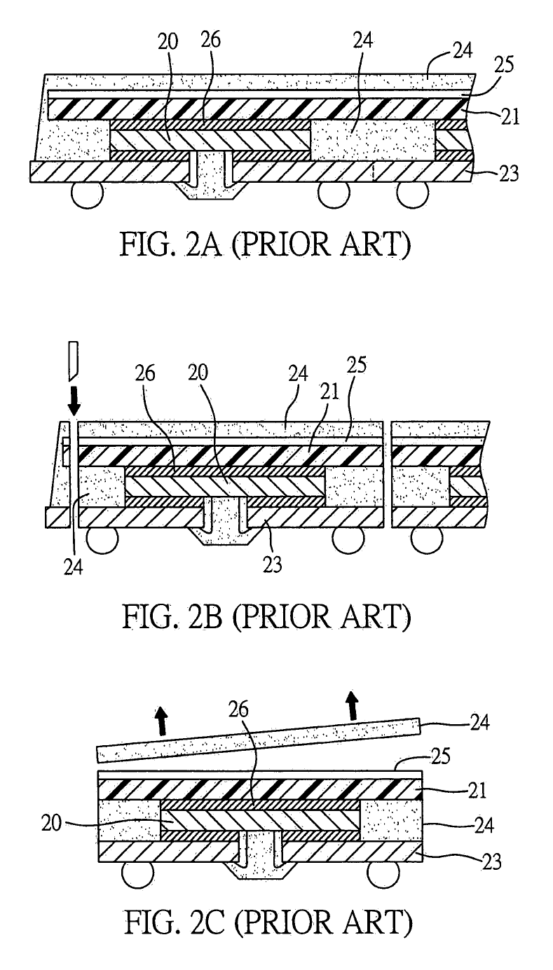

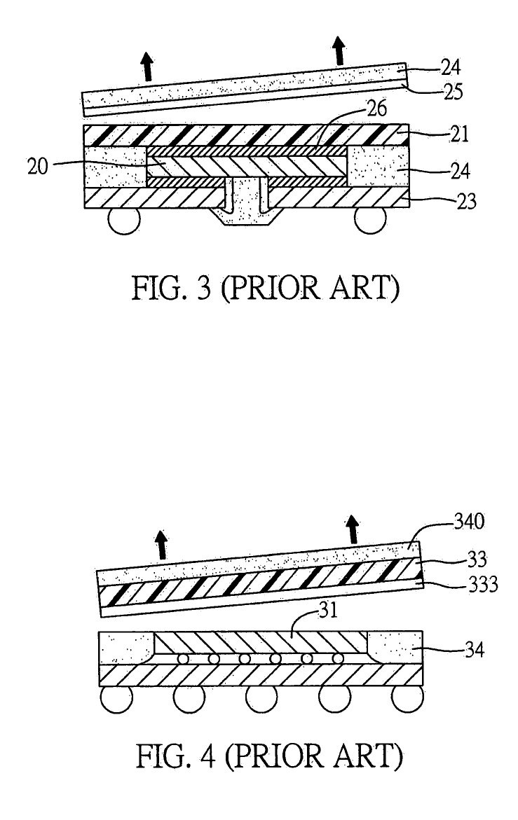

### DETAILED DESCRIPTION OF PREFERRED EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawings. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

### First Embodiment

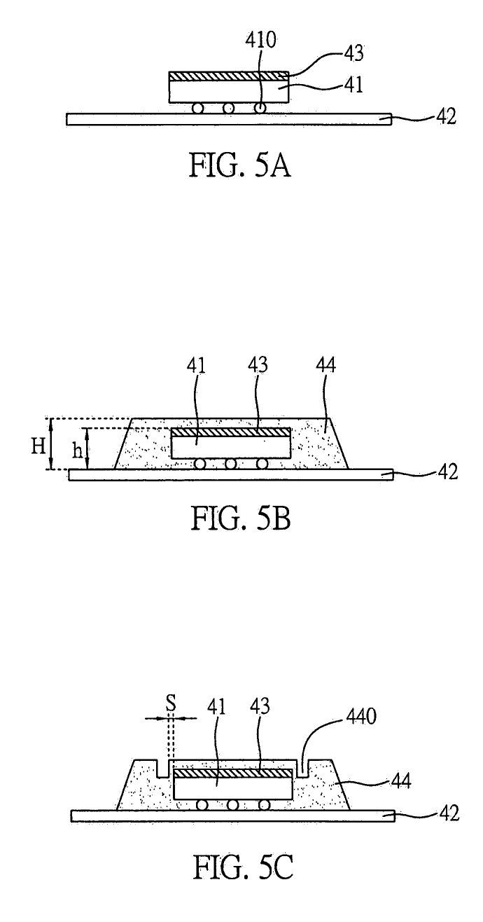

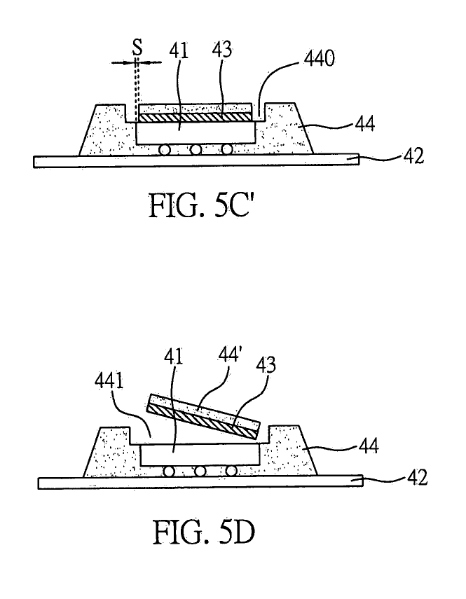

FIGS. 5A to 5D are schematic views showing a semiconductor package capable of dissipating heat, and a method for fabricating the same according to a first embodiment of the present invention.

As shown in FIG. 5A, a semiconductor chip 41 is mounted and electrically connected to a chip carrier 42, wherein an interfacial layer 43 is disposed on a surface of the semiconductor chip 41 that is not attached to the chip carrier 42. The chip carrier 42 may be a ball grid array (BGA) substrate or a land grid array (LGA) substrate. The semiconductor chip 41 may be a flip-chip semiconductor chip having an active surface thereof electrically connected to the chip carrier 42 via a plurality of conductive bumps 410. The interfacial layer 43 may be a polyimide tape (P.I. tape) adhered on the semiconductor chip 41, an epoxy resin applied on the semiconductor chip 41, or an organic layer such as wax formed on the semiconductor chip 41, such that the bonding force between the interfacial layer 43 and an encapsulant 44 subsequently formed is relatively greater than the bonding force between the interfacial layer 43 and the semiconductor chip 41, so as to remove the interfacial layer 43 and the encapsulant 44 from the semiconductor chip 41 facilely.

Referring to FIG. 5B, the chip carrier 42 mounted with the semiconductor chip 41 and the interfacial layer 43 is disposed in a mold cavity (not shown), and a molding process is performed, so as to form the encapsulant 44 on the chip carrier 42 for encapsulating the interfacial layer 43 and the semiconductor chip 41. Furthermore, the interfacial layer 43 is spaced apart from the top roof of the mold cavity at an adequate distance, such that the distance H between the top surface of the encapsulant 44 and the top surface of the chip carrier 42 is 0.05 to 0.3 mm greater than the distance h between the top surface of the interfacial layer 43 and the top surface of the chip carrier 42. That is to say, the top surface of the encapsulant 44 is 0.05 to 0.3 mm higher than the top surface of the interfacial layer 43. As a result, after the mold is clamped, the present invention can prevent the semiconductor chip 41 from bearing the stress and pressure from the mold, thereby improving the yield and reliability of products. Preferably, the distance H is 0.2 mm greater than the distance h.

Next, referring to FIG. 5C, a cutting process such as laser cutting is performed to cut the encapsulant 44 along the periphery of the interfacial layer 43 so as to form a groove 440. The groove 440 may have a depth at least as deep as the interfacial layer 43 (i.e. the bottom surface of the groove 440 is coplanar with that of the interfacial layer 43). Preferably, the bottom surface of the groove 440 is 0.05 to 0.1 mm deeper than that of the interfacial layer 43.

Furthermore, as shown in FIG. 5C, a portion of the encapsulant 44 may protrude from a lateral side of the semiconductor chip 41 with an extent S of 0 to 0.1 mm, wherein the extent S is preferably 0.05 mm. Alternatively, as shown in FIG. 5C′, a portion of the encapsulant 44 and a portion of the interfacial layer 43 may be removed during the formation of the groove 440 with an extent S of 0 to 0.1 mm, wherein the extent S is preferably 0.05 mm.

Referring to FIG. 5D, a removing process is performed to remove the interfacial layer 43 and a portion of the encapsulant 44 that is formed on the interfacial layer 43 (herein referred to as the encapsulant 44′). This thereby forms a recess 441 corresponding in position to the semiconductor chip 41 in the encapsulant 44, so as to expose a surface of the semiconductor chip 41 from the encapsulant 44.

Moreover, the present invention also discloses a heat sink package structure comprising: a chip carrier 42; a semiconductor chip 41 mounted and electrically connected to the chip carrier 42; an encapsulant 44 formed on the chip carrier 42 for encapsulating the semiconductor chip 41, wherein the encapsulant 44 is formed with a recess structure 441 corresponding in position to the semiconductor chip 41 so as to expose a surface of the semiconductor chip 41 from the encapsulant 44, such that heat generated by the semiconductor chip 41 during operation can be efficiently dissipated to the external environment or open air.

### Second Embodiment

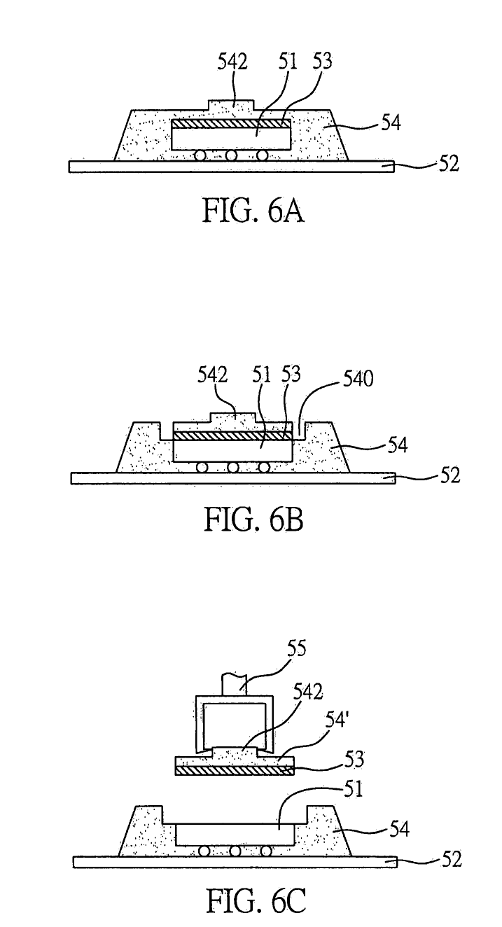

FIGS. 6A to 6C are schematic views showing a semiconductor package capable of dissipating heat, and a method for fabricating the same according to a second embodiment of the present invention. The semiconductor package of the second embodiment is substantially similar to that of the foregoing embodiment. However, one of the major differences between these two embodiments is that a protruding portion is formed on an encapsulant 54 of the second embodiment, so as to facilitate subsequent removal of a portion of the encapsulant 54.

Referring to FIG. 6A, a molding process is performed, wherein a chip carrier 52 mounted with a semiconductor chip 51 and an interfacial layer 53 is disposed in a mold cavity of a mold (not shown). Moreover, a top portion of the mold cavity further comprises a recessed structure for receiving the packaging resin such that, when an encapsulant 54 encapsulating the semiconductor chip 51 and the interfacial layer 53 is formed, a protruding portion 542 corresponding in position to the interfacial layer 53 can be formed on a top surface of the encapsulant 54.

Next, as shown in FIG. 6B, the encapsulant 54 is cut along the periphery of the interfacial layer 53 so as to form a groove 540 around the interfacial layer 53.

Referring to FIG. 6C, once the protruding portion 542 is clamped by a clamp 55 and detached from the semiconductor chip 51, the interfacial layer 53 and a portion of the encapsulant 54 (herein referred to as the encapsulant 54′) are removed from the semiconductor chip 51 effortlessly, thereby exposing the semiconductor chip 51 from the encapsulant 54.

### Third Embodiment

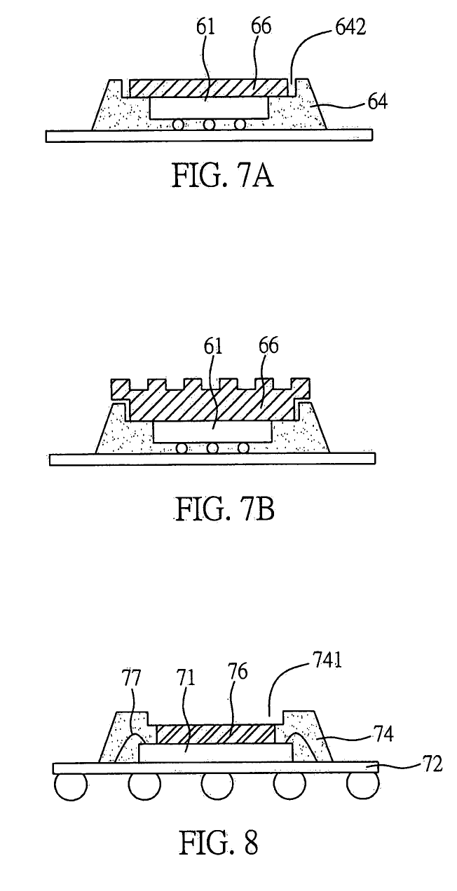

FIGS. 7A and 7B are schematic views of a semiconductor package, which is capable of dissipating heat and fabricated according to a third embodiment of the present invention. The semiconductor substrate of the second embodiment is substantially similar to that of the foregoing embodiments. However, one of the major differences between these embodiments is that an external heat-dissipating member 66 such as an external heat slug for greatly improving heat dissipation efficiency is disposed in a recess structure 641 on a surface of a semiconductor chip 61 that is uncovered by an encapsulant 64. Furthermore, the external heat-dissipating member 66 may be a flat plate or having at least a surface thereof formed with a plurality of protruding and/or denting portions.

### Fourth Embodiment

FIG. 8 is a schematic view of a semiconductor package capable of dissipating heat and fabricated according to a fourth embodiment of the present invention. One of the major characteristic features of the fourth embodiment is that a wire-bonded semiconductor chip 71 is mounted on a chip carrier 72 through a non-active surface of the semiconductor chip 71, wherein that the semiconductor chip 71 is electrically connected to the chip carrier 72 through a plurality of bonding wires 77. Moreover, a material layer 76 such as a dummy chip or a heat-dissipating member may be mounted on an active surface of the semiconductor chip 71, wherein the material layer 76 may further comprise an interfacial layer (not shown) mounted thereon. However, once the molding process is completed, the interfacial layer and a portion of an encapsulant formed on the interfacial layer are removed so as to form a recess structure 741 exposing the material layer 76, thereby enhancing heat dissipation of the semiconductor chip 71.

It should be noted that the size and location of the material layer 76 are not limited as long as it does not interfere with the bonding wires 77, and thickness of the material layer 76 should be slightly higher than the highest point of a wire loop of the bonding wires 77.

### Fifth Embodiment

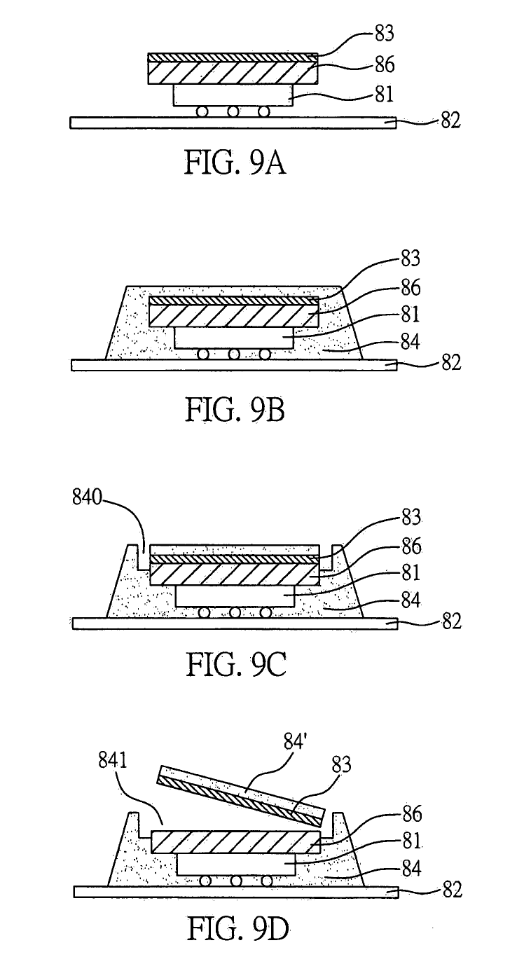

FIGS. 9A to 9D are schematic views of a semiconductor package capable of dissipating heat, and a method for fabricating the same according to a fifth embodiment of the present invention.

As shown in FIG. 9A, a semiconductor chip 81 is mounted on and electrically connected to a chip carrier 82. Moreover, a heat-dissipating member 86 having an interfacial layer 83 formed thereon is mounted on a surface of the semiconductor chip 81 that is free of the chip carrier 82. The size of the heat-dissipating member 86 may be larger than or equal to the size of the semiconductor chip 81.

Referring to FIG. 9B, a molding process is performed to form an encapsulant 84 on the chip carrier 82 for encapsulating the semiconductor chip 81, the heat-dissipating member 86 and the interfacial layer 83. The encapsulant 84 is about 0.05 to 0.3 mm, and preferably 0.2 mm, higher than the interfacial layer 83, so as to prevent cracking of the semiconductor chip 81 during the molding process.

Next, as shown in FIG. 9C, the encapsulant 84 is cut along edges of the interfacial layer 83 and the heat-dissipating member 86 so as to form a groove 840. The groove 840 is at least as deep as the interfacial layer 83. Preferably, the groove 840 is 0.05 to 0.1 mm deeper than the interfacial layer 83. Furthermore, the width of the groove 840 ranges between 0 and 0.1 mm, and is preferably 0.05 mm. In addition, the groove 840 may be formed next to or right on the interfacial layer 83.

Referring to FIG. 9D, a removing process is performed to remove the interfacial layer 83 and a portion of the encapsulant 84 formed on the interfacial layer 83 (herein referred to as the encapsulant 84′). Because the interfacial layer 83 is made of a tape, an epoxy resin, or an organic layer such as wax, the bonding force between the interfacial layer 83 and the encapsulant 84 is comparatively greater than that between the interfacial layer 83 and the heat-dissipating member 86. Therefore the interfacial layer 83 and the encapsulant 84′ formed thereon can be easily removed to form a recess structure 841, so as to expose the heat dissipating member 86 from the encapsulant 84 and dissipate heat generated by the semiconductor chip 81.

### Sixth Embodiment

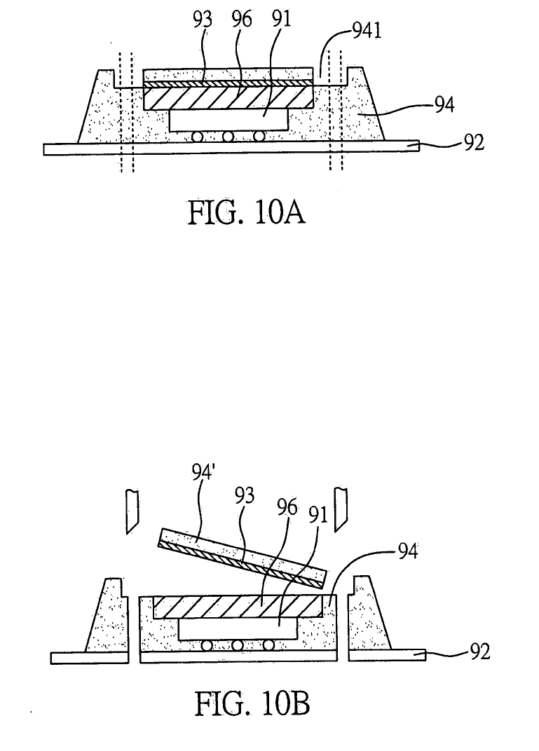

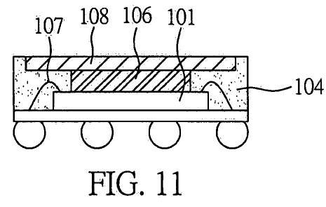

FIGS. 10A and 10B are schematic views of a semiconductor package capable of dissipating heat, and a method for fabricating the same according to a sixth embodiment of the present invention. One of the major differences between the sixth embodiment and the foregoing embodiments is that the width of a cut formed around the periphery of an interfacial layer is wider than that of a predefined size-cutting line of the package structure.

Referring to FIG. 10A, a semiconductor chip 91 is mounted on a chip carrier 92, and then a heat-dissipating member 96 formed with an interfacial layer 93 is mounted on a surface of the semiconductor chip 91 free of the chip carrier 92. Next, a molding process is performed so as to form on the chip carrier 92 an encapsulant 94 encapsulating the semiconductor chip 91, the heat-dissipating member 96 and the interfacial layer 93. Then, the encapsulant 94 is cut along the periphery of the interfacial layer 93 so as to form a groove 941, wherein the width of the groove 941 is greater than that of a predefined size-cutting line of the package structure (as shown in dashed lines of FIG. 10A).

Subsequently, as shown in FIG. 10B, the package structure is cut along a predefined size-cutting line, and the interfacial layer 93 and a portion of the encapsulant 94 formed on the interfacial layer 93 (herein referred to as the encapsulant 94′) are removed, so as to expose an upper surface of the heat-dissipating member 96 from the encapsulant 94. This thereby allows the heat generated by the semiconductor chip 91 to be dissipated to the external environment through the heat dissipating member 96. Moreover, as the cutting path of the package structure does not pass through the heat-dissipating member 96, lateral surfaces of the heat-dissipating member 96 can be covered by the encapsulant 94. As a result, it prevents the burr problem and wearing of the cutting tools caused by cutting the heat-dissipating member 96, and thus decreases cost of production.

### Seventh Embodiment

FIG. 11 is a schematic view of a semiconductor package, which is capable of dissipating heat and fabricated according to a seventh embodiment of the present invention. One of the major differences between the seventh embodiment and the foregoing embodiment is that a wire-bond semiconductor chip 101 is employed in this embodiment. The wire-bond semiconductor chip 101 is mounted on and electrically connected to a chip carrier 102 via a plurality of bonding wires 107, wherein an active surface of the wire-bond semiconductor chip 101 further accommodate a material layer 106 disposed thereon and a heat-dissipating member 108 mounted on the material layer 106. The material layer 106 may be a dummy chip or a heat-dissipating member. Furthermore, the heat-dissipating member 108 is exposed from the encapsulant 104, such that heat generated by the semiconductor chip 101 can be efficiently dissipated to the external environment via the material layer 106 and the heat-dissipating member 108.

### Eighth Embodiment

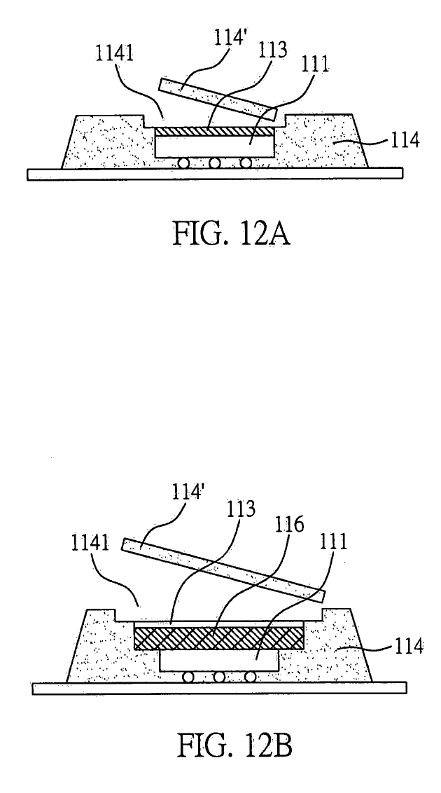

FIGS. 12A and 12B are schematic views of a semiconductor package capable of dissipating heat, which is fabricated according to an eighth embodiment of the present invention.

Referring to FIG. 12A, one of the major differences between the eighth embodiment and the foregoing embodiments is that an interfacial layer 113 of this embodiment is made of a material such as gold (Au) and nickel (Ni), so as to make the bonding force between the interfacial layer 113 and a semiconductor chip 111 greater than that between the interfacial layer 113 and an encapsulant 114. Therefore, a portion of the encapsulant 114 (herein referred to as the encapsulant 114′) positioned on the interfacial layer 113 can be easily removed from the interfacial layer 113 during a removing process, so as to form a recess structure 1141 in the encapsulant 114 in position corresponding to the semiconductor chip 111. This thereby exposes the interfacial layer 113 from the encapsulant 114, so as to dissipate heat generated by the semiconductor chip 111 to the external environment via the interfacial layer 113.

Alternatively, as shown in FIG. 12B, a heat-dissipating member 116 having the interfacial layer 113 is disposed on the semiconductor chip 111. The interfacial layer 113 is made of metal, such as gold (Au) and nickel (Ni), so as to make the bonding force between the interfacial layer 113 and the heat dissipating member 116 greater than that between the interfacial layer 113 and the encapsulant 114. Accordingly, the encapsulant 114′ located on the interfacial layer 113 can be easily removed from the interfacial layer 113 during a removing process, so as to forming a recess structure 1141 in the encapsulant 114 in position corresponding to the semiconductor chip 111, thereby dissipating heat generated by the semiconductor chip 111 to the external environment via the heat dissipating member 116 and the interfacial layer 113.

### Ninth Embodiment

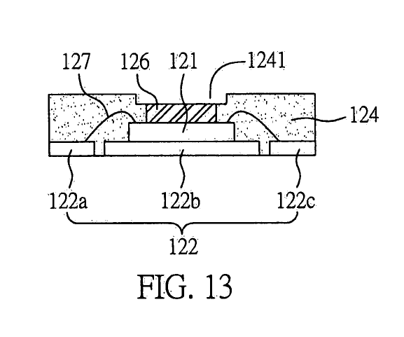

FIG. 13 is a schematic view of a semiconductor package fabricated according to a ninth embodiment of the present invention, which can dissipate heat efficiently. Referring to FIG. 13, one of the major differences of the ninth embodiment is that a Quad Flat No-Lead (QFN) leadframe 122 is employed to act as a chip carrier of a semiconductor chip 121. The semiconductor chip 121 is mounted to a die pad 122b of the QFN leadframe 122 via a non-active surface of the semiconductor chip 121 and electrically connected to a plurality of leads 122a and 122c of the QFN leadframe 122 via bonding wires 127, so as to electrically connect to an external device via the leads 122a and 122c. Furthermore, the QFN package may further comprise a material layer 126 such as a dummy chip or a heat-dissipating member that is disposed on an active surface of the semiconductor chip 121 without interfering with the layout of the bonding wires 127; and an encapsulant 124 encapsulating the semiconductor chip 121, wherein a recess structure 1241 positioned corresponding to the semiconductor chip 121 may be formed in the encapsulant 124 so as to expose the material layer 126, thereby dissipating heat generated by the semiconductor chip 121 via the material layer 126.

To be concluded from the above, primary features of the semiconductor package of the present invention and the fabrication method thereof includes attaching and electrically connecting a semiconductor chip to a chip carrier; applying an interfacial layer or attaching a heat dissipating member having an interfacial layer on the semiconductor chip; forming an encapsulant on the chip carrier for encapsulating the semiconductor chip and the interfacial layer or the heat dissipating member having the interfacial layer, wherein a space is kept between the top surface of the encapsulant and the top surface of the interfacial layer so as to prevent cracking of the semiconductor chip during the molding process; subsequently, cutting the encapsulant along the periphery of the interfacial layer or the periphery of the heat dissipating member having the interfacial layer; and removing the excess or unneeded encapsulant from the interfacial layer so as to dissipate heat and avoid mold flash, wherein the interfacial layer can be left over or removed with the excess encapsulant.

Accordingly, during fabrication of the semiconductor package of the present invention, a common polishing process existed in the prior art can be omitted so as to prevent exposing the semiconductor chip to the external environment, thereby avoiding problems such as cracking the semiconductor chip and increasing the cost of production. Moreover, during the cutting process, instead of cutting through the interfacial layer or the heating-dissipating member, the encapsulant of the present invention is cut along the periphery of the interfacial layer or the periphery of the heating-dissipating member, thereby preventing problems such as burr and wearing of cutting tools as well as reducing the cost of the cutting process.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A method for fabricating a semiconductor package capable of dissipating heat, comprising the steps of:
attaching and electrically connecting a semiconductor chip to a chip carrier;
forming an interfacial layer on a surface of the semiconductor chip not attaching to the chip carrier;
performing a molding process so as to form an encapsulant on the chip carrier for encapsulating the semiconductor chip and the interfacial layer;
performing a cutting process so as to cut the encapsulant along periphery of the interfacial layer with a cutting depth being set at least as deep as the interfacial layer; and
performing a removing process for removing a portion of the encapsulant formed on the interfacial layer.

2. The method of claim 1, wherein the chip carrier is a substrate or a leadframe, and the semiconductor chip is electrically connected to the chip carrier by means of flip-chip techniques or means of wire-bonding techniques.

3. The method of claim 2, wherein the interfacial layer is formed on a non-active surface of the semiconductor chip when the semiconductor chip is electrically connected to the chip carrier by the flip-chip techniques, or alternatively, formed on a material layer that is formed in advance on an active surface of the semiconductor chip when the semiconductor chip is electrically connected to the chip carrier by the wire-bonding techniques.

4. The method of claim 3, wherein the material layer is a dummy chip or a heat-dissipating member.

5. The method of claim 3, wherein the material layer is at least partially exposed from the encapsulant so as to improve heat dissipation of the semiconductor chip.

6. The method of claim 1, wherein the interfacial layer is made of a material capable of forming a relatively greater bonding force between the interfacial layer and the encapsulant than that between the interfacial layer and the semiconductor chip, such that the interfacial layer and a portion of the encapsulant formed thereon can be removed at once during the removing process, so as to expose the semiconductor chip.

7. The method of claim 6, wherein the interfacial layer is one selected from the group consisting of a tape, an epoxy resin, and an organic layer.

8. The method of claim 6, further comprising mounting an external heat-dissipating member on a surface of the semiconductor chip uncovering by the encapsulant.

9. The method of claim 1, wherein the interfacial layer is made of a material capable of forming a relatively greater bonding force between the interfacial layer and the semiconductor chip than that between the interfacial layer and the encapsulant, such that a portion of the encapsulant formed on the interfacial layer can be removed during the removing process, so as to expose the interfacial layer.

10. The method of claim 9, wherein the interfacial layer is a metal layer.

11. The method of claim 1, wherein a top surface of the encapsulant is 0.05 to 0.3 mm higher than a top surface of the interfacial layer, and preferably about 0.2 mm.

12. The method of claim 1, wherein the encapsulant is cut along the periphery of the interfacial layer so as to form a groove having a depth at least as deep as the interfacial layer, and preferably 0.05 to 0.1 mm deeper than the interfacial layer.

13. The method of claim 1, wherein a portion of the encapsulant may protrude from a lateral side of the semiconductor chip with an extent of 0 to 0.1 mm, and preferably 0.05 mm.

14. The method of claim 1, wherein a portion of the encapsulant and a portion of the interfacial layer may be removed with an extent of 0 to 0.1 mm, and preferably 0.05 mm.

15. The method of claim 1, wherein the encapsulant further comprises a protruding portion, such that a portion of the encapsulant formed on the interfacial layer can be readily removed by the use of a clamp.

16. The method of claim 1, wherein a width of a cut formed around the periphery of the interfacial layer is wider than that of a predefined size-cutting line of the semiconductor package.

17. A method for fabricating a semiconductor package capable of dissipating heat, comprising the steps of:
mounting and electrically connecting a semiconductor chip to a chip carrier;
attaching a heat-dissipating member on a surface of the semiconductor chip not attaching to the chip carrier, wherein a surface of the heat-dissipating member not attaching to the semiconductor chip is provided with an interfacial layer;
performing a molding process to form an encapsulant on the chip carrier for encapsulating the semiconductor chip, the heat-dissipating member, and the interfacial layer;
performing a cutting process to cut the encapsulant along periphery of the interfacial layer and the heat dissipating member with a cutting depth being set at least as deep as the interfacial layer; and
performing a removing process to remove a portion of the encapsulant formed on the interfacial layer.

18. The method of claim 17, wherein the chip carrier is a substrate or a leadframe, and the semiconductor chip is electrically connected to the chip carrier by means of flip-chip techniques or means of wire-bonding techniques.

19. The method of claim 18, wherein the heat-dissipating member is disposed on a non-active surface of the semiconductor chip when the semiconductor chip is electrically connected to the chip carrier by the flip-chip techniques, or alternatively, disposed on a material layer that is formed in advance on an active surface of the semiconductor chip when the semiconductor chip is electrically connected to the chip carrier by the wire-bonding techniques.

20. The method of claim 19, wherein the material layer is a dummy chip or a heat-dissipating member.

21. The method of claim 17, wherein the interfacial layer is made of a material capable of forming a relatively greater bonding force between the interfacial layer and the encapsulant than that between the interfacial layer and the heat-dissipating member, such that the interfacial layer and a portion of the encapsulant formed thereon can be removed at once during the removing process, so as to expose the heat dissipating member.

22. The method of claim 21, wherein the interfacial layer is one selected from the group consisting of a tape, an epoxy resin, and an organic layer.

23. The method of claim 17, wherein the interfacial layer is made of a material capable of forming a relatively greater bonding force between the interfacial layer and the heat-dissipating member than that between the interfacial layer and the encapsulant, such that a portion of the encapsulant formed on the interfacial layer can be removed during the removing process, so as to expose the interfacial layer.

24. The method of claim 23, wherein the interfacial layer is a metal layer.

25. The method of claim 17, wherein a top surface of the encapsulant is 0.05 to 0.3 mm higher than a top surface of the interfacial layer, and preferably about 0.2 mm.

26. The method of claim 17, wherein the encapsulant is cut along the periphery of the interfacial layer so as to form a groove having a depth at least as deep as the interfacial layer, and preferably 0.05 to 0.1 mm deeper than the interfacial layer.

27. The method of claim 17, wherein a portion of the encapsulant may protrude from a lateral side of the semiconductor chip with an extent of 0 to 0.1 mm, and preferably 0.05 mm.

28. The method of claim 17, wherein a portion of the encapsulant and a portion of the interfacial layer may be removed with an extent of 0 to 0.1 mm, and preferably 0.05 mm.

29. The method of claim 17, wherein the encapsulant further comprises a protruding portion, such that a portion of the encapsulant formed on the interfacial layer can be readily removed by the use of a clamp.

30. The method of claim 17, wherein a width of a cut formed around the periphery of the interfacial layer is wider than that of a predefined size-cutting line of the semiconductor package.

31. A semiconductor package capable of dissipating heat, at least comprising:
a chip carrier;
a semiconductor chip mounted on and electrically connected to the chip carrier; and
an encapsulant formed on the chip carrier for encapsulating the semiconductor chip, wherein the encapsulant is formed with a recess corresponding in position to the semiconductor chip so as to expose the semiconductor chip from the encapsulant.

32. The structure of claim 31, wherein an interfacial layer is further formed on the semiconductor chip.

33. The structure of claim 32, wherein the interfacial layer is a metal layer.

34. The structure of claim 31, wherein an external heat-dissipating member is further formed on the semiconductor chip.

35. The structure of claim 31, wherein a material layer is further formed on the semiconductor chip.

36. The structure of claim 35, wherein the material layer is a dummy chip or a heat-dissipating member disposed thereon.

37. The structure of claim 31, wherein the chip carrier is a substrate or a leadframe, and the semiconductor chip is electrically connected to the chip carrier by means of flip-chip techniques or means of wire-bonding techniques.

38. A semiconductor package capable of dissipating heat, at least comprising:
a chip carrier;
a semiconductor chip mounted on and electrically connected to the chip carrier;
a heat-dissipating member mounted on the semiconductor chip; and
an encapsulant formed on the chip carrier for encapsulating the semiconductor chip and the heat-dissipating member, wherein the encapsulant is formed with a recess corresponding in position to the heat-dissipating member so as to expose at least a portion of the heat-dissipating member from the encapsulant.

39. The structure of claim 38, wherein an interfacial layer is further formed on the heat-dissipating member.

40. The structure of claim 39, wherein the interfacial layer is a metal layer.

41. The structure of claim 38, wherein the chip carrier is a substrate or a leadframe, and the semiconductor chip is electrically connected to the chip carrier by means of flip-chip techniques or means of wire-bonding techniques.

42. The structure of claim 38, wherein a material layer is further formed between the heat-dissipating member and the semiconductor chip.

43. The structure of claim 42, wherein the material layer is a dummy chip or a heat-dissipating member.

44. A semiconductor package capable of dissipating heat, at least comprising:
a chip carrier;
a semiconductor chip mounted on and electrically connected to the chip carrier;
a heat-dissipating member mounted on the semiconductor chip; and
an encapsulant formed on the chip carrier for encapsulating the semiconductor chip and at least a lateral surface of the heat-dissipating member, wherein an upper surface of the heat-dissipating member is exposed from the encapsulant.

45. The structure of claim 44, wherein an interfacial layer is further formed on a surface of the heat-dissipating member.

46. The structure of claim 45, wherein the interfacial layer is a metal layer.

47. The structure of claim 44, wherein the chip carrier is a substrate or a leadframe, and the semiconductor chip is electrically connected to the chip carrier by means of flip-chip techniques or means of wire-bonding techniques.

48. The structure of claim 44, wherein a material layer is further formed between the heat-dissipating member and the semiconductor chip.

49. The structure of claim 48, wherein the material layer is a dummy chip or a heat-dissipating member.
